(19) United States
(12) Patent Application Publication
(10) Pub. No.: US 2005/0255241 A1
(43) Pub. Date: Nov. 17, 2005

(54) Gas supply device and treating device

(75) Inventors: Seishi Murakami, Yamanashi (JP); Yoshiyuki Hanada, Yamanashi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Tokyo Electron Limited, Tokyo (JP)

(21) Appl. No.: 10/504,989

(22) PCT Filed: Feb. 20, 2003
(86) PCT No.: PCT/JP03/01890

§ 371 Date: Aug. 19, 2004

(30) Foreign Application Priority Data
Jun. 21, 2000 (JP) 2000-186947

(51) Int. Cl. C23C 16/00

(52) U.S. Cl. 427/248.1; 118/715; 118/725

(57) ABSTRACT

A gas shower head installed opposedly to the surface of a substrate, having a large number of holes in the surface thereof opposed to the substrate, and feeding multiple types of film forming gases fed from a gas feed passage simultaneously to the substrate through the holes, comprising a shower head body having a plurality of metal members with contact faces locally joined to each other by metal diffusion by heating the plurality of the metal members under specified temperature conditions in the stacked state in vertical direction and a plurality of gas flow passages passing through the inside of the shower head body so as to cross the contact faces and formed independently of each other for each type of the film forming gases so that these film forming gases are not mixed with each other, wherein the temperature conditions are such that the locally joined portions by metal diffusion can be separated from each other by a reheating performed later.

### FIELD OF THE INVENTION

The present invention relates to a gas shower head for feeding gases to a substrate of a semiconductor wafer and the like and a film forming apparatus and method for forming a film on a surface of the substrate by using the gas shower head.

### BACKGROUND OF THE INVENTION

In the process of manufacturing a semiconductor device, a film may be formed on an object to be processed by a chemical vapor deposition (CVD) process. Further, as one of the apparatuses for performing such a film forming process, a single-wafer film forming apparatus may be used. Such a film forming apparatus has a processing vessel including therein a mounting table for loading thereon, e.g., a semiconductor wafer (hereinafter, referred to as a “wafer” for simplicity) and a gas shower head installed opposedly to the mounting table, for feeding film forming gases to a wafer surface. Formed in the shower head are gas flow passages so that plural species of film forming gases can be diffused in horizontal directions to be uniformly fed upon the wafer surface without being mixed with each other. Further, the shower head is configured to have a structure of, e.g., three-layered metal plates (diffusion plates made of metal). The metal plates are fixed to each other by, e.g., bolts, and installed in the processing vessel. The film forming gases fed from an upside flow downward through the gas flow passages penetrating the three-layered metal plates and are then uniformly fed on the entire surface of the wafer through a plurality of holes formed on a bottom surface of the shower head. The plural species of film forming gases are simultaneously fed to the gas shower head. For example, in order to form a titanium nitride (TiN) film, a TiCl₄ gas and a NH₃ gas are supplied into the processing vessel without being mixed with each other via the gas shower head.

However, the gas shower head for supplying the plural species of film forming gases has the following problem.

As illustrated in FIG. 7, minute convexo concave that cannot be removed by mechanical polishing may exist on contact faces (abutment surfaces) P2 of each of the metal plates fixed by screws. Accordingly, even if the metal layers are fixed by screws, the contact faces thereof are not completely adhered to each other, thereby generating fine gaps of a few μm between the faces as shown in FIG. 8. Therefore, the TiCl₄ gas and the NH₃ gas may be mixed together through the gaps. In this case, undesired reaction by-products may be generated in the gas shower head.

In other words, both of the film forming gases may react by a thermal energy, so that reaction generally occurs near the surface of the wafer, the other side thereof being heated. Since, however, the gas shower head is disposed close to the wafer, the gas shower head is also heated by a heat radiated from the wafer. Accordingly, part of both film forming gases may react also in the gas shower head. The reaction by-products resulting therefrom may cause particulate contamination.

Meanwhile, there is a method of preventing gap generation by applying a solder material on the abutment surfaces of the diffusion plates when joining the diffusion plates. However, in case of employing such a method, the solder material may react with the film forming gases near the gas flow passages inside the diffusion plates, thereby the reaction by-product causing particulate contamination. Specifically, in case a solder material such as Ag, Cu and/or Zn is used in the above-described method in addition to the base metal of the gas shower head, Cl or F moiety of the film forming gases may react on the solder material, thereby generating reaction by-products. Further, if the solder material is used, it is difficult to disassemble the joined diffusion plates, rendering it cumbersome to carry out a cleaning process thereon.

### SUMMARY OF THE INVENTION

It is, therefore, a primary object of the present invention to provide a technique for preventing a different types of film forming gases from being mixed with each other due to gaps formed between contact faces of metal members stacked in the gas shower head for supplying the plural species of film forming gases to a substrate. It is another object of the present invention to prevent generation of particulate by-products by applying the inventive gas shower head to a film forming apparatus.

In accordance with one aspect of the present invention, there is provided a gas shower head installed opposedly to a surface of a substrate, having a plurality of holes in a surface thereof opposed to the surface of the substrate, for feeding a plural species of film forming gases, each of the plural species of film forming gases being fed simultaneously to the substrate through the holes, the gas shower head including: a shower head body having a plurality of metal members with contact faces locally joined to each other by a metal diffusion by heating the plurality of metal members at an elevated temperature in their stacked state; and a plurality of gas flow passages passing through the contact faces in the shower head body and formed independently of each other for each of the plural species of film forming gases so that the film forming gases passing therethrough are not mixed with each other, wherein, at the elevated temperature, the contact faces locally joined by the metal diffusion are separable by a reheating thereof.

In accordance with the present invention, since the contact faces of the metal members employed in constructing the gas shower head are joined locally and chemically by heating the metal members, it is possible to greatly reduce minute gaps that cannot be removed by a mechanical joining, the gaps being formed by convexo concave on the contact faces. Consequently, gas leakages are avoided in each of the gas flow passages and, simultaneously, the plural species of film forming gases are not mixed with each other, thereby the undesirable reaction by-products can be prevented from being generated in the gas shower head.

The metal members employed in the present invention are made of nickel and/or a nickel alloy; and preferably, nickel;

In accordance with another aspect of the invention, there is provided a film forming apparatus including: a processing vessel having a mounting table for loading thereon a substrate; a heat source for heating the substrate loaded on the mounting table; and a gas shower head having the above-described features, which is installed in the processing vessel.

In accordance with a further aspect of the invention, there is provided a film forming method for performing a film forming process by feeding film forming gases from a gas shower head, installed opposedly to a substrate loaded on a mounting table in a processing vessel, to a surface of the substrate, the film forming method comprising the steps of: assembling the gas shower head by locally joining contact faces of a plurality of metal members to each other by a metal diffusion by heating the plurality of metal members at an elevated temperature in their stacked state; and feeding a plural species of film forming gases to the substrate via the gas shower head without being mixed with each other in the gas shower head, thereby performing the film forming process on the surface of the substrate, wherein, at the elevated temperature, the contact faces locally joined by the metal diffusion are separable by a reheating thereof.

Preferably, the assembly step further includes the steps of: pressing the plurality of metal members in their stacked state with a torque; and installing the gas shower head in the processing vessel.

The pressing step may be performed, e.g., by binding the metal members with a screw.

Further, the torque is preferably greater or equal to 15 kg/cm² and, preferably, about 30 kg/cm².

For example, in the assembly step, the gas shower head is heated by using a heat source for heating the substrate and/or a heat source installed in the gas shower head.

The temperature employed during the assembly step is preferably higher than or equal to 500° C. and, preferably, ranges from 500° C. to 550° C.

Further, in the assembly step, it is preferable to maintain the temperature at the elevated level for about 12 hours.

Preferably, the method further includes the step of separating the plurality of metal members by heating the gas shower head after the completion of the other steps.

In such separating step, the gas shower head is heated by using the heat source for heating the substrate and/or the heat source installed in the gas shower head.

Preferably, the gas shower head is reheated at a temperature higher than or equal to 550° C. in the separating step.

### BRIEF DESCRIPTION OF THE DRAWINGS

The above and other objects and features of the present invention will become apparent from the following description of preferred embodiments, given in conjunction with the accompanying drawings, in which:

FIG. 1 shows a vertical sectional view of a film forming apparatus in accordance with a preferred embodiment of the present invention;

FIG. 2 illustrates a vertical sectional view of a configuration of a shower head body installed in the film forming apparatus;

FIG. 3 describes a vertical sectional view of the disassembled shower head body;

FIG. 4 depicts a flow chart showing an exemplary process performed in the preferred embodiment;

FIG. 5 presents a characteristic graph depicting the result of a test that has been carried out in order to confirm the superior effect of the preferred embodiment;

FIG. 6 represents a vertical sectional view of a shower head body of a film forming apparatus in accordance with another preferred embodiment of the present invention;

FIG. 7 provides a schematic view illustrating a problem present in a conventional gas shower head; and

FIG. 8 offers a schematic view showing the problem of a conventional gas shower head.

### BEST MODE FOR CARRYING OUT THE INVENTION

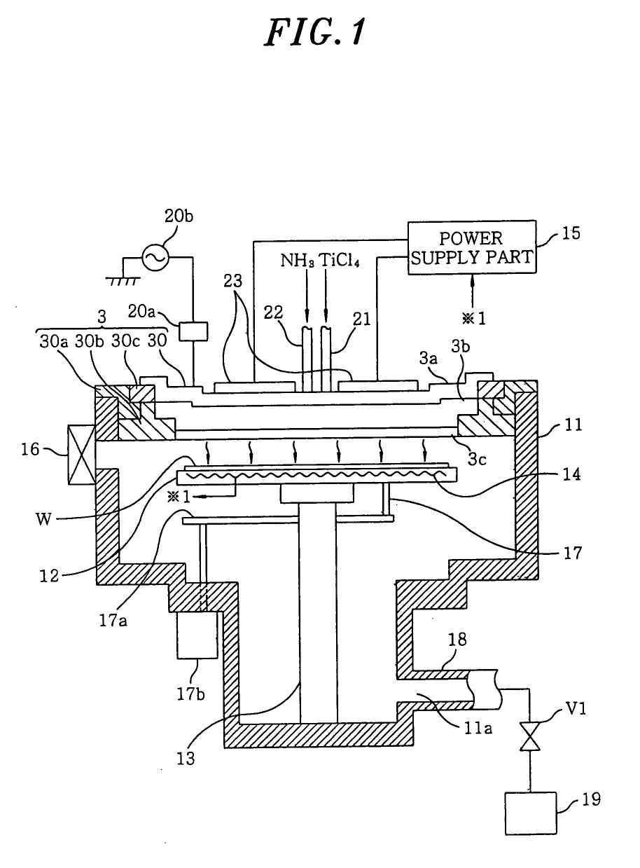

Hereinafter, preferred embodiments of a film forming apparatus employing a gas shower head in accordance with the present invention will be described with reference to FIGS. 1 to 3. A reference numeral 11 indicates a chamber constructing a processing vessel made of, e.g., aluminum. Installed inside the chamber 11 are a mounting table 12, which has a plate shape slightly larger than a wafer W, for mounting thereon the wafer W as a substrate; and a supporting body 13 for supporting the mounting table 12 from a bottom side. Buried inside the mounting table 12 is a first heater 14 made of, e.g., a resistance heating material, which constructs a heat source. During a film forming process, the first heater 14 uniformly heats up an entire surface of, e.g., the wafer W. Or, the first heater 14 heats the gas shower head to a predetermined temperature when the gas shower head is assembled and disassembled, wherein the assembly and disassembly thereof will be described later. For these purposes, a power supply unit 15 installed outside a film forming apparatus, for example, controls a temperature of the first heater 14 to obtain a required temperature.

Installed on a ceiling portion of the chamber 11 is a gas shower head 3 including a shower head body 30, a lid 30a supporting a side portion of the gas shower head body 30, an insulating sealing member 30c and a quartz filling material 30b. As will be described later, the gas shower head body 30 includes three metal plates 3a, 3b and 3c, wherein an outer peripheral portion of the metal plate 3a is supported by the lid 30a via the insulating sealing member 30c. The insulating sealing member 30c, which is made of, e.g., Al₂O₃, is used for insulating the chamber 11 and the gas shower head 3 in case a high frequency power is supplied. In the meantime, the ring-shaped quartz filling material 30b is installed between an outer circumference of the gas shower head body 30 and the chamber 11. In this way, a dead space of the chamber 11 is buried, thereby enabling a satisfactory film forming process.

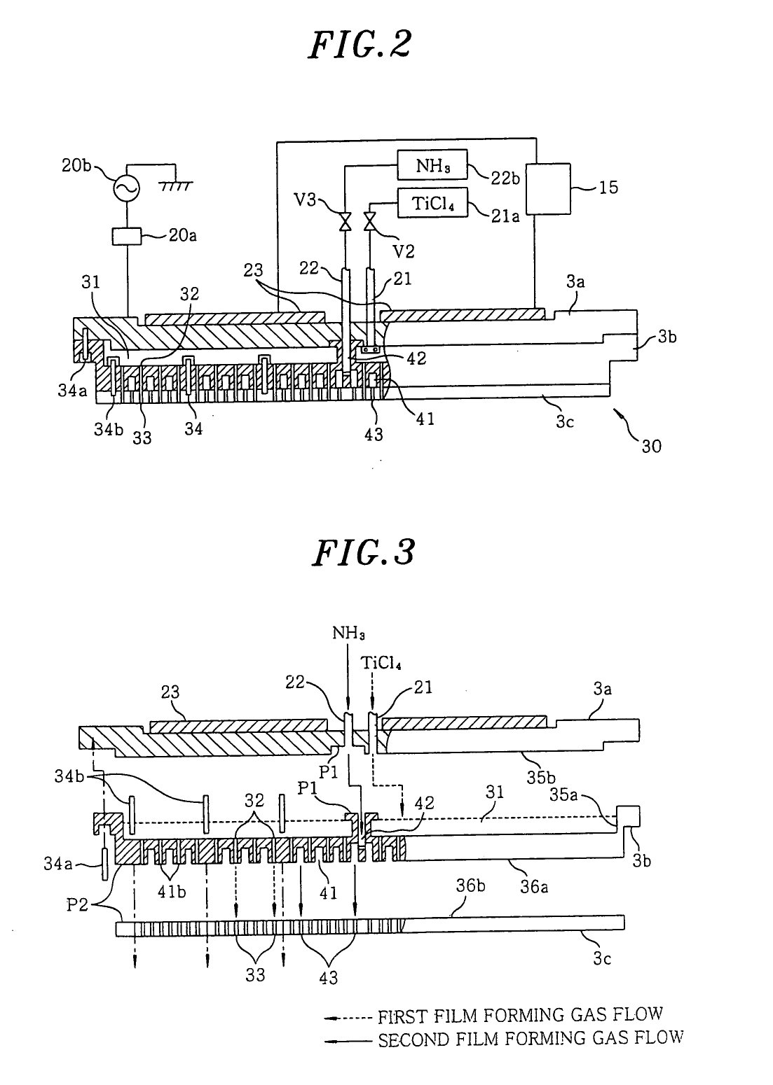

The gas shower head 3 is connected to gas supply lines 21 and 22 forming gas feed passages. A plurality of holes 33 and 34 are formed on a bottom surface of the gas shower head 3 (see FIGS. 2 and 3), so that film forming gases can be supplied to a surface of the wafer W mounted on the mounting table 12 through the holes 33 and 34. Further, a second heater 23 is installed on a top surface of the gas shower head 3. As described with respect the first heater 14, the second heater 23 is controlled by the power supply unit 15 to obtain a predetermined temperature. Furthermore, a high frequency power supply unit 20b is connected to the shower head 3 via a matching unit 20a, whereby the film forming gases fed to the wafer W during the film forming process become plasma, thereby facilitating the film forming method.

Installed on a side portion of the chamber 11 is a gate valve 16 for loading and unloading the wafer W. A vertically movable lift pin 17 (the actual number of the lift pins 17 is, e.g., three) is installed at the mounting table 12, capable of being projected and subsided, so that the wafer W can be loaded on the mounting table 12 via the gate valve 16 by a transfer arm that is not illustrated. A vertical movement of the lift pin 17 is carried out by an operation of an elevation mechanism 17b via a supporting member 17a supporting a bottom portion of the lift pin 17. Further, an exhaust port 11a is formed around the supporting body 13 as illustrated in FIG. 1. A vacuum pump 19 is connected to the exhaust port 11a via an exhaust line 18 and a valve V1.

Hereinafter, the shower head body 30 that is a principal part of this preferred embodiment will be described with reference to FIGS. 2 and 3. FIG. 2 shows a vertical sectional view presenting an overall structure of the shower head body 30. As illustrated in FIG. 2, the shower head body 30 has a configuration including vertically laminated three metal members, i.e., metal plates 3a, 3b and 3c made of, e.g., nickel. Contact faces (abutment surfaces) of each of the metal plates 3a, 3b and 3c are processed by, e.g., a machining, a mechanical polishing, a chemical polishing, an electrolytic polishing, or the like. A surface roughness Ra thereof ranges, e.g., from 3.2 to 0.2.

FIG. 3 illustrates disassembled three-layered metal plates 3a, 3b and 3c. Herein, each of the metal plates is referred to as an upper portion 3a, an intermediate portion 3b and a lower portion 3c for the sake of simplicity. Contact faces P1 between the upper portion 3a and the intermediate portion 3b and contact faces P2 between the intermediate portion 3b and the lower portion 3c are respectively joined together by a diffusion without gaps formed therebetween. A space 31 is formed between the upper portion 3a and the intermediate portion 3b, and a space 41 is formed between the intermediate portion 3b and the lower portion 3c. Formed at the intermediate portion 3b are a large number of first gas flow passages 32 penetrating the lower portion 3c from the space 31 and a second gas flow passage 42 communicating with the space 41 without communicating with the space 31. Formed at the lower portion 3c are a large number of first holes 33 communicating with the first gas flow passages 32 and a large number of second holes 43 communicating with the space 41. Further, the upper portion 3a and the intermediate portion 3b may be fixed to each other by a bolt 34a (screw fixing). In the same manner, the intermediate portion 3b and the lower portion 3c may be fixed to each other by a bolt 34b.

As described above, the gas supply lines 21 and 22 are respectively connected to the top surface of the upper portion 3a. The gas supply line 21 communicates with the space 31 while the gas supply line 22 communicates with the space 41 through the second gas flow passage 42.

Hereinafter, shapes of the space 31 and the space 41 will be described with reference to FIG. 3. The space 31 is a cylinder shaped vacancy surrounded by a cylindrical recessed portion 35a formed on, e.g., a top surface of the intermediate portion 3b and a bottom surface 35b of the upper portion 3a, which forms a singular space communicating in a horizontal direction. The space 41 is formed by a large number of cylindrical protruded portions 41b (convexity) formed on, e.g., a bottom surface of the intermediate portion 3b. In other words, a void portion (a groove portion) adjacent to each of the protruded portions 41b communicates in horizontal directions. The space 41 is a singular space communicating in a horizontal direction between the bottom surface 36a of the intermediate portion 3b and the top surface 36b of the lower portion 3c.

Accordingly, the film forming gas supplied from the gas supply line 21 is uniformly distributed in the space 31 in horizontal directions and then heads toward the first holes 33 via the first gas flow passages 32. Meanwhile, the film forming gas supplied from the gas supply line 22 to the space 41 via the second gas flow passage 42 is uniformly distributed in the space 41 in horizontal directions and then heads toward the second holes 43. In other words, two types of the film forming gases respectively passing through the gas supply lines 21 and 22 are independently supplied to the wafer W without being mixed with each other. They are initially mixed with each other in a processing vessel. Such a gas shower head 3 is referred to as a matrix type.

Hereinafter, upstreams of the gas supply lines 21 and 22 will be described. The upstream of the gas supply line 21 is connected to a first film forming gas (TiCl₄) source 21a via a valve V2. Further, the upstream of the gas supply line 22 is connected to a second film forming gas (NH₃) source 22a via a valve V3. The first and the second film forming gas sources 21a and 22a store therein source gases, which are used as film forming elements, respectively. The first film forming gas source 21a, for example, gasifies each liquid source to be vaporized by using a carrier gas during a film forming process and then sends the vapor to the gas shower head 3 via the gas supply line 21. The second film forming gas source 22a, for example, sends vapor of the second film forming gas to the gas shower head 3 via the gas supply line 22 during the film forming process.

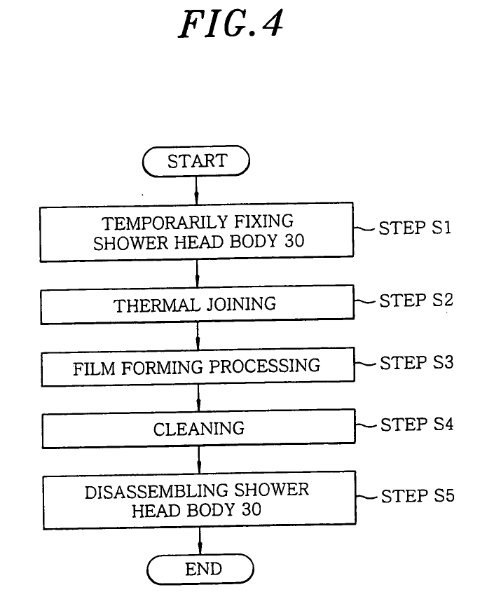

Next, an operation of the above-described preferred embodiment of the present invention will be described with reference to a flow chart shown in FIG. 4. First of all, before the film is formed on the surface of the wafer W, the gas shower head 3 is assembled. Such an assembly step may be performed by joining three metal plates that have been disassembled for, e.g., a cleaning process, so as to construct the shower head body 30. That is, the upper portion 3a, the intermediate portion 3b and the lower portion 3c are adhered to each other in a certain direction and location, e.g., outside the chamber 11. Further, with a torque being greater than or equal to, e.g., 15 kg/cm² and, preferably, being about 30 kg/cm², the upper portion 3a and the intermediate portion 3b are temporarily fixed by the bolt 34a; and the intermediate portion 3b and the lower portion 3c are temporarily fixed by the bolt 34b (step S1). And then, the temporarily fixed gas shower head 3 is installed in a certain location of the chamber 11. A nitrogen gas is supplied from, e.g., a nitrogen gas supply unit that is not illustrated, to the chamber 11 with a rate of 3600 cc/min and, at the same time, an exhaust flow is controlled so that a pressure therein can be 1.33322×10² Pa (1 Torr). In this state, a heating inside the chamber 11 is initiated by using the first and the second heaters 14 and 23. Accordingly, at both the contact faces P1 between (a bottom surface of) the upper portion 3a and (a top surface of) the intermediate portion 3b and the contact faces P2 between a surface of the protruded portion 41b (convexity) on the bottom surface 36a of the intermediate portion 3b and the top surface 36b of the lower portion 3c, nickels of adjacent metal members adhere to each other. Consequently, a metal diffusion is performed on an outermost layer of the metal members while filling fine gaps between each of the contact faces P1 and P2. The heating is continued until a bonding force between each of the contact faces P1 and P2 is obtained to prevent each contact face from being separated, for instance, even when the bolts 34a and 34b are extracted. In this way, the assembly of the gas shower head 3 is completed. Specifically, the contact faces P1 and P2 need to be bonded with a predetermined bonding force. For example, in case an area of the contact faces P2 [an area of a surface of the protruded portion 41b on the bottom surface 36a of the intermediate portion 3b] is greater than or equal to 50 cm² or, preferably, 70 cm², it is preferable to maintain the heating for 12 hours at an elevated temperature (the temperature on the contact faces) of over 500° C. and, preferably, ranging from 500° C. to 550° C.

Subsequently, a film forming process is performed to the wafer W. After the gate valve 16 is opened, the transfer arm that is not shown enters the chamber 11 and delivers the wafer W to the lift pin 17. Next, the wafer W is mounted on a center of the mounting table 12 by lowering the lift pin, thereby beginning the film forming process of step S3. During this step, a surface temperature of the wafer W is increased up to a predetermined process temperature of, e.g., 450° C. to 700° C., by the first and/or the second heaters 14 and 23. Further, after the valve V1 is opened, the chamber 11 is exhausted via the exhaust port 11a by using the vacuum pump 19, to thereby maintain a certain vacuum degree therein. Thereafter, the valves V2 and V3 are opened and then film forming gases start to be supplied to the gas shower head 3. At this time, a controller that is not illustrated controls a mass flow of each film forming gas so that a certain mass flow of a TiCl₄ gas and an NH₃ gas can head toward the gas shower head 3, via, e.g., a mass flow controller that is not shown.

The TiCl₄ gas and the NH₃ gas are uniformly distributed into each flow passage in the gas shower head 3 without being mixed with each other while directing downward and then uniformly supplied to an entire surface of the wafer W through the first and the second holes 33 and 43 being separately installed. Further, each of the film forming gases is decomposed near the surface of the wafer W due to a thermal energy radiated from the wafer W. Next, a TiN thin film is formed on the surface of the wafer W by a chemical vapor reaction due to the thermal energy. After a predetermined period of time, the valves V2 and V3 are closed and the supply of the film forming gases is stopped. In addition, the heating by the first heater 14 is stopped, and then a predetermined subsequent process is performed in the chamber 11. Thereafter, the wafer W is unloaded in a reverse order of a loading sequence.

After the film forming process is performed on the predetermined number of wafers, a cleaning gas, e.g., a ClF₃ gas, is transferred from a gas supply source that is not shown and supplied into the chamber 11 through the gas shower head 3, so that unnecessarily formed films are removed inside the chamber 11 (cleaning) (step S4).

Next, the gas shower head 3 is disassembled again in order to clean an inner portion thereof (step S5). A disassembly of the gas shower head 3 is basically performed in a reverse order of the assembly process described in the steps S1 and S2. To be specific, the gas shower head 3 is detached from the chamber 11, and the bolts 34a and 34b are loosened by, e.g., about 1 mm, in comparison with the temporarily fixed state described in the step S1. Next, when the gas shower head 3 is returned and heated in the chamber 11, the bonding force on the contact faces P1 and P2 is weakened, thereby separating the metal plates constructing the shower head body 30.

At this time, a heating condition is approximately equal to that in the step S2. However, it is preferable to set a heating temperature to be equal to or slightly higher than that of the assembly step. In case of the shower head body 30 exemplified above, if a heating temperature of the assembly step is 500° C., it is preferable to set the temperature of the disassembly step to be higher than or equal to 500° C. or, specifically, higher than or equal to 550° C. After the heating is stopped and the shower head body 30 is cooled down, the upper portion 3a, the intermediate portion 3b and the lower portion 3c are respectively separated and then detached from the chamber 11. Then, by loosening the bolts 34a and 34b, the disassembly step is completed.

As described above, in accordance with this preferred embodiment, since surfaces of a plurality of metal plates constructing the gas shower head 3 [the shower head body 30] are chemically joined by a heating, gaps between the metal surfaces (contact faces) that can not be eliminated by a mechanical joining, e.g., a screw fixing, i.e., the gaps being formed by fine irregularities on the metal surfaces (the contact faces) that can not be avoided by a mechanical polishing, are considerably reduced. Thus, in film forming gas flow passages formed by crossing contact faces of the metal plates, a gas leakage through the contact faces can be completely prevented. Accordingly, it is possible to prevent the different types of film forming gases from being mixed with each other in the gas shower head 3 and, at the same time, completely restrict reaction by-products generated from the gaseous mixture.

In other words, in this preferred embodiment, the film forming gases are prevented from being mixed with each other completely. And also, each of the film forming gases can be uniformly distributed on an entire surface of the wafer W with high accuracy depending on an arrangement of the holes 32 (32a and 32b) of the gas shower head 3, thereby improving an in-surface uniformity of a thin film. Further, since the reaction by-products are prevented from being generated in the gas shower head 3, causes for generation of particles are removed. Consequently, it is possible to completely avoid a possibility of a contamination due to the particles on the wafer W, thereby improving a yield of products.

Furthermore, in this preferred embodiment, since there is no need to perform a soldering or a welding to join metal surfaces, abutment surfaces can be simply separated in a same order as the assembly sequence of the gas shower head 3. Therefore, it is possible to easily perform a maintenance process such as a cleaning of each gas flow passage formed in the gas shower head 3.

Moreover, although, in this preferred embodiment, every step including an assembly and a disassembly of the gas shower head 3 is performed in the chamber 11 in which the film forming process is executed, such steps can be performed in, e.g., a heating furnace separately installed aside from the chamber 11. Therefore, a maintenance time can be greatly reduced, and an operating rate of an apparatus and a yield of products can be improved. In addition, the metal plates constructing the gas shower head 3 can be made of any metals other than nickel as long as it does not react on film forming gases and can be joined and separated by a metal diffusion through a heating thereof. For example, aluminum and its alloy, a nickel-based alloy, a chrome-based alloy, and the like can provide same effects. Also, as long as the same effects are obtained, a plurality of metal plates can be made of different types of metals. Specifically, there may be employed a combination of a metal plate made of nickel and that made of aluminum, for example. Further, either the first heater 14 and/or the second heater 23 may be used for assembling and disassembling the gas shower head 3.

Additionally, a structure of the shower head body 30 is not limited to the above-described preferred embodiment. The shower head body 5 illustrated in FIG. 6, which is used for forming, e.g., a Ti film, a TiN film, and the like, may provide effects equal to those of the aforementioned preferred embodiment. Hereinafter, a structure of the shower head body 5 will be simply described. The shower head body 5 includes a multiplicity of, e.g., three metal plates. Such metal plates are respectively referred to as an upper portion 5a, an intermediate portion 5b and a lower portion 5c sequentially from upside in their stacked order. In this case, each of the contact faces Q1 and Q2 is adhered by a metal diffusion. In addition, the three-layer metal plates can be fixed by a bolt 50 penetrating from a bottom surface of the lower portion 3c to the upper portion 3a. Formed between the upper portion 5a and the intermediate portion 5b is a space 51 obtained by forming a recessed portion on a top surface of the intermediate portion 5b. Formed between the intermediate portion 5b and the lower portion 5c is a space 61 obtained by forming a recessed portion on a bottom surface of the intermediate portion 5b.

Formed at the intermediate portion 5b are a large number of first gas flow passages 52 communicating from the space 51 to the lower portion 5c and a second gas flow passage 62 communicating from the space 61 to the upper portion 5a without communicating with the space 51. Formed at the lower portion 5c are a large number of first holes 53 communicating with the first gas flow passages and a large number of second holes 63 communicating with the space 61. The first holes 53 and the second holes 63 are arranged without being overlapped with each other, for example, alternatively.

A top surface of the upper portion 5a is connected to a gas supply line 54 for supplying a first film forming gas and a gas supply line 64 for supplying a second film forming gas. Further, formed inside the upper portion 5a are a third gas flow passage 55 communicating from the gas supply line 54 to the space 51 and a fourth gas flow passage 65 communicating from the gas supply line 64 to the second gas flow passages 62. Therefore, the first film forming gas is supplied to the wafer W through a path corresponding to the gas supply line 54→ the third gas flow passage 55→ the space 51→ the first gas flow passages 52→ the first holes 53. The second film forming gas is supplied to the wafer W through a path corresponding to the gas supply line 64→ the fourth gas flow passage 65→ the second gas flow passage 62→ the space 61→ the second holes 63. The first film forming gas and the second film forming gas are not mixed with each other in the shower head body 5.

Further, metals used in the shower head body 5 are identical to those used in the aforementioned preferred embodiment. Thus, it is possible to join and separate the metals by a heating thereof under an elevated temperature identical to that of the aforementioned preferred embodiment.

### Embodiment

In order to check a relationship between a heating temperature and a bonding force between each of nickels in the aforementioned preferred embodiments, one pair of specimens made of nickels is prepared. Next, a test is executed to examine a relationship between the bonding force thereof and a heating temperature. A contact faces between the specimens used in this test is 25 cm². The film forming apparatus in accordance with the preferred embodiment of the present invention is used as a heating apparatus. Further, in the film forming apparatus, a pressure in the chamber is maintained at 1.33322×10² Pa (1 Torr) while a nitrogen gas is supplied thereinto at a flow rate of 3600 cc/min. Moreover, the test is executed with the heating duration of 12 hours.

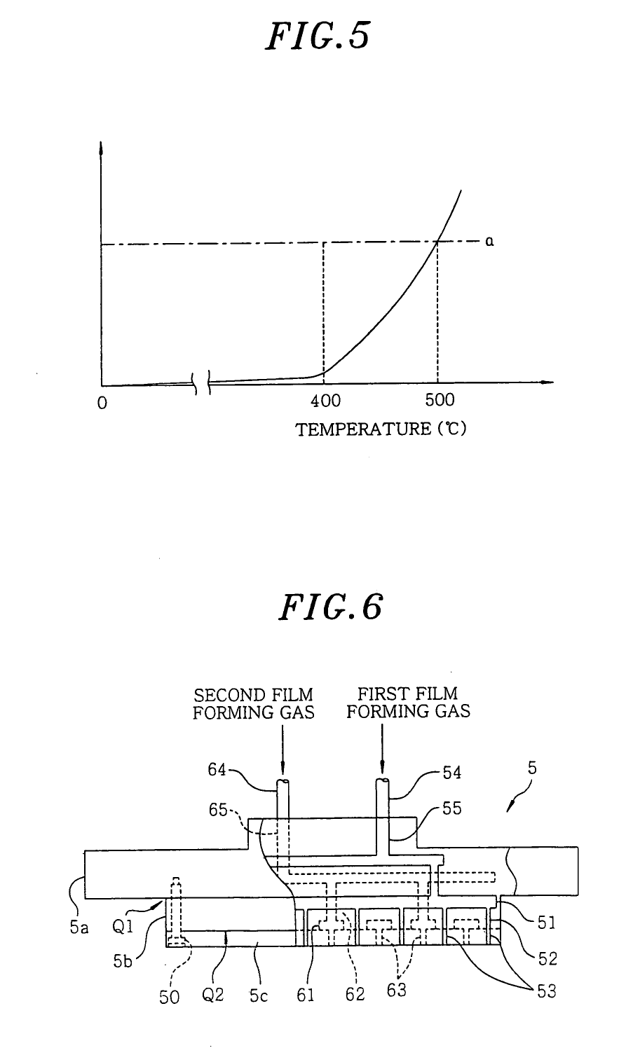

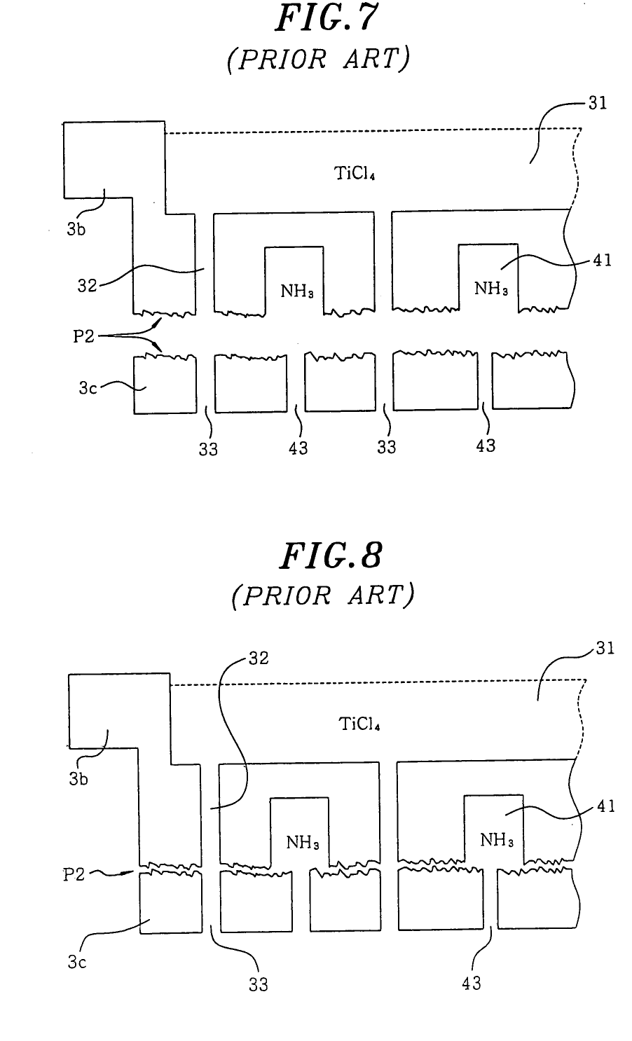

FIG. 5 provides a characteristic graph illustrating the result of this test. As shown in FIG. 5, the bonding force of nickels is sharply increased when a temperature of the specimen is higher than or equal to 450° C. Further, a reference mark a indicated by a dashed dot line represents a bonding force at which a contact faces P1 are not separated in case an area of the contact faces P1 is greater than or equal to 50 cm² or, preferably, 70 cm², in the gas shower head 3 of this preferred embodiment. Thus, it is shown that the strong bonding force is formed between the metal surfaces joined by a metal diffusion, such that fine gaps between the contact faces are considerably reduced.

While the invention has been shown and described with respect to the preferred embodiments, it will be understood by those skilled in the art that various changes and modifications may be made without departing from the spirit and scope of the invention as defined in the following claims.

1. A gas shower head installed opposedly to a surface of a substrate, having a plurality of holes in a surface thereof opposed to the surface of the substrate, for feeding a plural species of film forming gases fed from gas feed passages simultaneously to the substrate through the holes, the gas shower head comprising:
a shower head body having a plurality of metal members with contact faces locally joined to each other by a metal diffusion by heating the plurality of metal members at an elevated temperature in their stacked state; and
a plurality of gas flow passages passing through the contact faces in the shower head body and formed independently of each other for each of the plural species of film forming gases so that the film forming gases passing therethrough are not mixed with each other,
wherein, at the elevated temperature, the contact faces locally joined by the metal diffusion are separable by a reheating thereof.

2. The gas shower head of claim 1, wherein the plurality of metal members are made of nickel and/or a nickel alloy.

3. The gas shower head of claim 2, wherein the plurality of metal members are made of nickel.

4. (canceled)

5. A film forming method for performing a film forming process by feeding film forming gases from a gas shower head, installed opposedly to a substrate mounted on a mounting table in a processing vessel, to the substrate, the film forming method comprising the steps of:
assembling the gas shower head by locally joining contact faces of a plurality of metal members to each other by a metal diffusion by heating the plurality of metal members at an elevated temperature in their stacked state; and
feeding a plural species of film forming gases to the substrate via the gas shower head without being mixed with each other in the gas shower head, thereby performing the film forming process on the surface of the substrate,
wherein, at the elevated temperature, the contact faces locally joined by the metal diffusion are separable by a reheating thereof.

6. The film forming method of claim 5, wherein the assembly step further includes the steps of:
pressing the plurality of metal members in their stacked state with a torque; and
installing the gas shower head in the processing vessel.

7. The film forming method of claim 6, wherein the pressing step is performed by a screw fixing.

8. The film forming method of claims 6 or 7, wherein the torque is greater than or equal to 15 kg/cm².

9. The film forming method of claim 8, wherein the torque is about 30 kg/cm².

10. The film forming method of claim 5, wherein in the assembly step, the gas shower head is heated by using at least one of a heating unit for heating a substrate and a heating unit installed in the gas shower head.

11. The film forming method of claim 5, wherein the temperature employed during the assembly step is higher than or equal to 500° C.

12. The film forming method of claim 11, wherein the temperature employed during the assembly step ranges from 500° C. to 550° C.

13. The film forming method of claim 12, wherein in the assembly step, the temperature is maintained at the elevated level for about 12 hours.

14. The film forming method of claim 5, further including the step of separating the plurality of metal members by reheating the gas shower head after the completion of the other steps.

15. The film forming method of claim 14, wherein, in the separating step, the gas shower head is reheated by using the heating unit for heating the substrate and/or the heating unit installed in the gas shower head.

16. The film forming method of claim 15, wherein, in the separating step, the gas shower head is reheated at a temperature greater than or equal to 550° C.

17. A film forming apparatus comprising:
a processing vessel having a mounting table for mounting thereon a substrate;
a heating unit for heating a substrate loaded on the mounting table; and
a gas shower head installed, in the processing vessel, opposedly to a surface of a substrate, having a plurality of holes in a surface thereof opposed to the surface of the substrate, for feeding a plural species of film forming gases, each of the plural species of film forming gases being fed simultaneously to the substrate through the holes, and
wherein the gas shower head includes:
a shower head body having a plurality of metal members with contact faces locally joined to each other by a metal diffusion by heating the plurality of metal members at an elevated temperature in their stacked state; and
a plurality of gas flow passages passing through the contact faces in the shower head body and formed independently of each other for each of the plural species of film forming gases so that film forming gases passing therethrough are not mixed with each other,
wherein, at the elevated temperature, the contact faces locally joined by the metal diffusion are separable by a reheating thereof.

18. The film forming apparatus of claim 17, wherein the plurality of metal members are made of nickel and/or a nickel alloy.

19. The film forming apparatus of claim 18, wherein the plurality of metal members are made of nickel.
